(19) United States
(12) Patent Application Publication
(10) Pub. No.: US 2007/0035008 A1
(43) Pub. Date: Feb. 15, 2007

(54) Thin IC package for improving heat dissipation from chip backside

(75) Inventors: Cheng-Ting Wu, Tainan (TW); Shih-Feng Chiu, Tainan (TW); Tu-Tang Pan, Tainan (TW); Ting-Yuan Chen, Tainan (TW); Yu-Cheng Chang, Tainan (TW); Ming-Hung Su, Tainan (TW)

Correspondence Address: TROXELL LAW OFFICE PLLC, SUITE 1404, 5205 LEESBURG PIKE, FALLS CHURCH, VA, 22041, US

(73) Assignee: ChipMOS TECHNOLOGIES (Bermuda) LTD. ChipMOS TECHNOLOGIES INC.

(21) Appl. No.: 11/322,409

(22) Filed: Jan. 3, 2006

(30) Foreign Application Priority Data
Aug. 9, 2005 (TW) 094127021

(51) Int. Cl. H01L 23/12; H01L 23/053

(52) U.S. Cl. 257/700

(57) ABSTRACT

A thin IC package to enhance heat dissipation from the back surface of a chip, comprises a substrate, the chip, and an encapsulant where the substrate has an upper surface, a lower surface, and an opening to accommodate the chip. The chip is disposed in the opening of the substrate where the chip has an active surface, a back surface, and a plurality of bonding pads disposed on the active surface to electrically connect to the substrate. At least a slot is formed on the back surface of the chip. Preferably, a plurality of the slots on the back surface of the chip form a plurality of integral thermal fins therefrom. The encapsulant are formed on the upper surface of the substrate and in the opening to embed the chip with the back surface and the slots being exposed from the encapsulant to enhance the heat dissipation from the back surface of the chip and to enhance chip strength.

### FIELD OF THE INVENTION

The present invention relates to packaging technologies of an IC chip with an exposed back surface, and more particularly, to a thin IC package for improving heat dissipation from the back surface of the chip.

### BACKGROUND OF THE INVENTION

As the packaging technologies of integrated circuits moves toward lighter, thinner, shorter, and smaller, the demands for heat dissipation become stronger. Normally, a heat spreader is attached to a package to increase heat dissipation. However, the thickness of a heat spreader will add to the total package thickness, therefore, a package using exposed back surface of a chip to enhance heat dissipation was developed. A known IC package has a chip with an exposed backside is revealed in U.S. Pat. No. 5,696,666. As shown in FIG. 1, the IC package comprises a chip 10 and a substrate 20 with an opening 21 which penetrates from the upper surface 22 to the lower surface 23 of the substrate 20. Moreover, the opening 21 is square to accommodate the chip 10. The chip 10 is disposed in the opening 21 and is fixed by an adhesive tape during fabricating processes (not shown in figures). The active surface 11 of the chip 10 and the upper surface 22 of the substrate 20 is encapsulated by an encapsulant 30 with the back surface 12 of the chip 10 is exposed from the lower surface 23 of the substrate 20, so that the heat generated from the chip 10 under operation will be dissipated from the back surface 12 of the chip 10. However, the efficiency of heat dissipation of the chip 10 is directly related to the exposed area of the back surface 12 of the chip 10. The maximum exposed area of the chip 10 is determined by chip dimension and cannot be increased, therefore, the efficiency of heat dissipation is limited and can not be enhanced.

### SUMMARY OF THE INVENTION

The main purpose of the present invention is to provide a thermally-enhanced thin IC package with an exposed back surface of a chip. At least a slot is formed on the back surface of the chip where the slot and the back surface of the chip are exposed from an encapsulant to increase the exposed area of the chip to enhance heat dissipation. Moreover, the slot can enhance the chip strength or increase the adhesion to a heat spreader which can be implemented in BGA (Ball Grid Array) packages, QFN (Quad Flat Non-leaded) packages, or BCC (Bump Chip Carrier) packages.

The second purpose of the present invention is to provide a thermally-enhanced thin IC package with an exposed back surface of a chip, which comprises a chip having at least a slot, a plurality of external terminals, and an encapsulant having a bottom surface. The external terminals, the back surface and the slot of the chip are exposed from the bottom surface of the encapsulant. When the thin IC package is mounted to an exterior PCB (printed circuit board) by the external terminals, the slot and the back surface of a chip can be hidden between the thin IC package and the PCB from damages.

The third purpose of the present invention is to provide a thermally-enhanced thin IC package where at least a slot is formed on a back surface of a chip. The slot is not connected to the edges of the back surface of the chip to prevent overflowing of the encapsulant to ensure the slot and the back surface of the chip are exposed from the encapsulant.

The fourth purpose of the present invention is to provide a thermally-enhanced thin IC package where a plurality of slots are formed on a back surface of a chip. The slots on the back surface of the chip form a plurality of integral thermal fins therefrom in place of a conventional heat spreader.

The fifth purpose of the present invention is to provide a thermally-enhanced thin IC package where a plurality of slots are formed on a back surface of a chip. The slots are formed as laser marks as an identification of the package.

According to the present invention, an IC package comprises a chip, a substrate, and an encapsulant where the chip has an active surface and a back surface. A plurality of bonding pads are formed on the active surface and electrically connected to the substrate. At least a slot is formed on the back surface of the chip. The substrate has an upper surface, a lower surface, and an opening to accommodate the chip. The encapsulant is formed on the upper surface of the substrate and in the though hole to embed the chip with the slot and the back surface of the chip are exposed from the encapsulant. Accordingly, the slot is capable of enhancing heat dissipation, chip strength, adhesion to a heat spreader, or displacing a heat spreader.

### DESCRIPTION OF THE DRAWINGS

FIG. 1 is a cross-sectional view of a conventional BGA package with an exposed chip.

FIG. 2 is a cross-sectional view of a thermally-enhanced thin IC package according to the first embodiment of the present invention.

FIG. 3 shows an exposed back surface of a chip from the IC package according to the first embodiment of the present invention.

FIG. 4 is a cross-sectional view of a thermally-enhanced thin IC package according to the second embodiment of the present invention.

FIG. 5 is a cross-sectional view of a thermally-enhanced thin IC package according to the third embodiment of the present invention.

FIG. 6 shows an exposed back surface of a chip from the IC package according to the third embodiment of the present invention.

FIG. 7 is a cross-sectional view of a thermally-enhanced thin IC package according to the fourth embodiment of the present invention.

FIG. 8 is a top view of the thin IC package according to the fourth embodiment of the present invention.

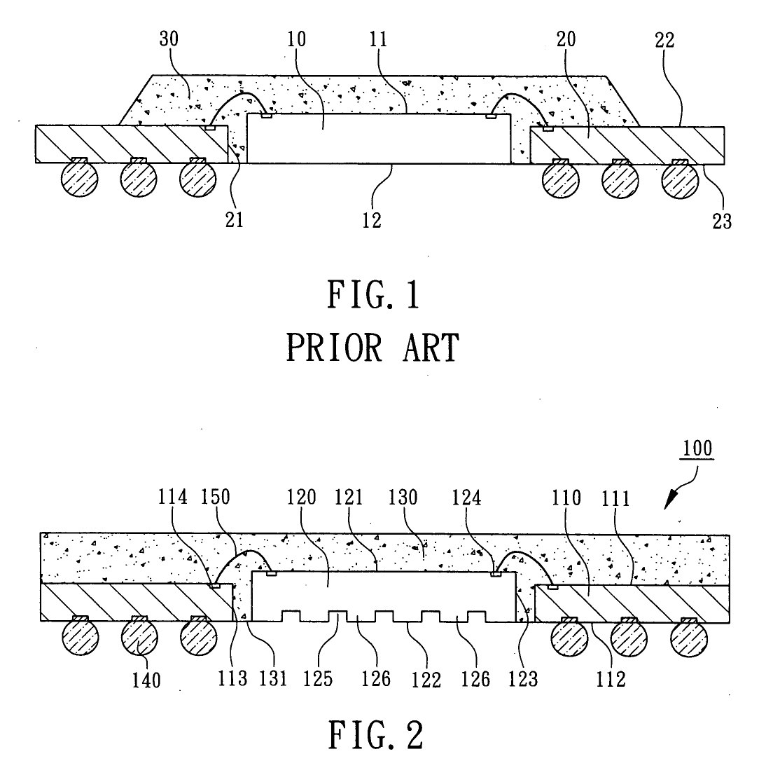

### DETAIL DESCRIPTION OF THE INVENTION

Please refer to the attached drawings, the present invention will be described by means of embodiment(s) below.

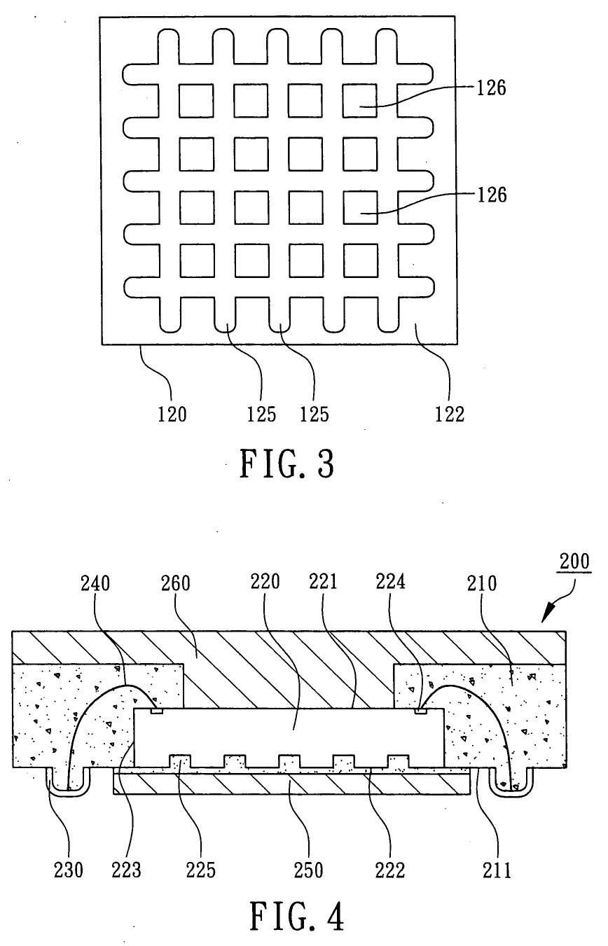

According to the first embodiment of the present invention, as shown in FIG. 2, a thin IC package 100 in ball grid array (BGA) type comprises a substrate 110, a chip 120, and an encapsulant 130 where the substrate 110 has an upper surface 111, a lower surface 112, and an opening 113 penetrating from the upper surface 111 to the lower surface 112 to accommodate the chip 120. During the assembling processes, the chip 120 is disposed in the opening 113 of the substrate 110 by attaching to a temporary adhesive tape (not shown in the figures) adhering to the lower surface 112 of the substrate 110 without direct contact with the substrate 110. The chip 120 has an active surface 121, a back surface 122, and a plurality of sidewalls 123 between the active surface 121 and the back surface 122. A plurality of bonding pads 124 are formed on the active surface 121 and are electrically connected to the connecting pads 114 on the upper surface 111 of the substrate 110 by a plurality of bonding wires 150. A plurality of slots 125 are formed on the back surface 122 of the chip 120 to increase heat dissipation area of the back surface 122. In this embodiment, as shown in FIG. 3, the slots 125 are arranged like a net which can be formed by half wafer-sawing, laser inscribing, or chemical etching. The cross section of the slots 125 can be triangular, rectangular, or semi-circular. Preferably, the slots 125 are dense and shape the chip 120 to form a plurality of integral thermal fins 126 therefrom.

In this embodiment, the back surface 122 of the chip 120 is coplanar with the lower surface 112 of the substrate 110.

The encapsulant 130 is formed on the upper surface 111 of the substrate 110 and in the opening 113 to embed the chip 120. The encapsulant 130 covers the active surface 121 and the sidewalls 123 of the chip 120 and seals the bonding wires 150 with the back surface 122 of the chip 120 and the slots 125 are exposed from the bottom surface 131 of the encapsulant 130. The slots 125 can either connect or not connect to the edges of the back surface 122 of the chip 120. Preferably, as shown in FIG. 3, the slots 125 are not connected to the edges of the back surface 122 of the chip 120 to avoid overflowing of the encapsulant 130 over the slots 125. Furthermore, a plurality of solder balls 140 used as external terminals 140 are placed on the lower surface 112 of the substrate 110. In the present embodiment, the back surface 122 of the chip 120 and the external terminals 140 are exposed from the bottom surface 131 of the encapsulant 130 to hide the exposed back surface 122 of the chip 120 after SMT for protection. Preferably, the dimension of the encapsulant 130 is approximately equal to the dimension of the substrate 110 in sawing types, i.e., the peripheries of the encapsulant 130 are vertically aligned with the peripheries of the substrate 110 so that the upper surface 111 of the substrate 110 are completely covered by the encapsulant 130 to prevent warpage of the substrate 110.

Since the plurality of the slots 125 are formed on the back surface 122 of the chip 120 with the slots 125 and the back surface 122 of the chip 120 exposed from the encapsulant 130, the slots 125 can increase the heat dissipation area of the back surface 122 and improve the heat conductivity of the chip 120 to enhance heat dissipation efficiency of the thin package 100. In addition, these slots 125 can enhance the chip strength of the chip 120.

According to the second embodiment of the present invention, as shown in FIG. 4, a thin IC package 200 is a BCC (Bumped Chip Carrier) package. The thin package 200 comprises an encapsulant 210, a chip 220, and a plurality of external terminals 230 where the encapsulant 210 has a bottom surface 211. The external terminals 230 are exposed and extrude from the bottom surface 211 of the encapsulant 210, which are the extruded plated layers of BCC packages. The chip 220 has an active surface 221, a back surface 222, and a plurality of sidewalls 223 where a plurality of bonding pads 224 are formed on the active surface 221 and are electrically connected to the external terminals 230 by a plurality of bonding wires 240. A plurality of slots 225 are formed on the back surface 222. In this embodiment, the slots 225 may connects to the edges of the back surface 222 of the chip 220. The chip 220 is embedded in the encapsulant 210, wherein the active surface 221 and the sidewalls 223 of the chip 220 are covered by the encapsulant 210 with the back surface 222 and the slots 225 are exposed from the bottom surface 211 of the encapsulant 210. Preferably, the external terminals 230 are extruded from the bottom surface 211 of the encapsulant 210 and the back surface 222 of the chip 220 are exposed from the bottom surface 211 of the encapsulant 210. Therefore, after SMT, the exposed back surface 222 of the chip 220 is facing to an external printed circuit board (not shown in the figures), so that the possibility of damaging to the back surface 222 of the chip 220 is greatly reduced. Furthermore, a heat spreader 250 can be further attached to the back surface 222 of the chip 220. Through the slots 225 on the back surface 222 of the chip 220, the adhesion between the heat spreader 250 and the chip 220 can be enhanced. Preferably, another heat spreader 260 in the encapsulant 210 can attach to the active surface 221 of the chip 220 to further enhance the heat dissipation efficiency.

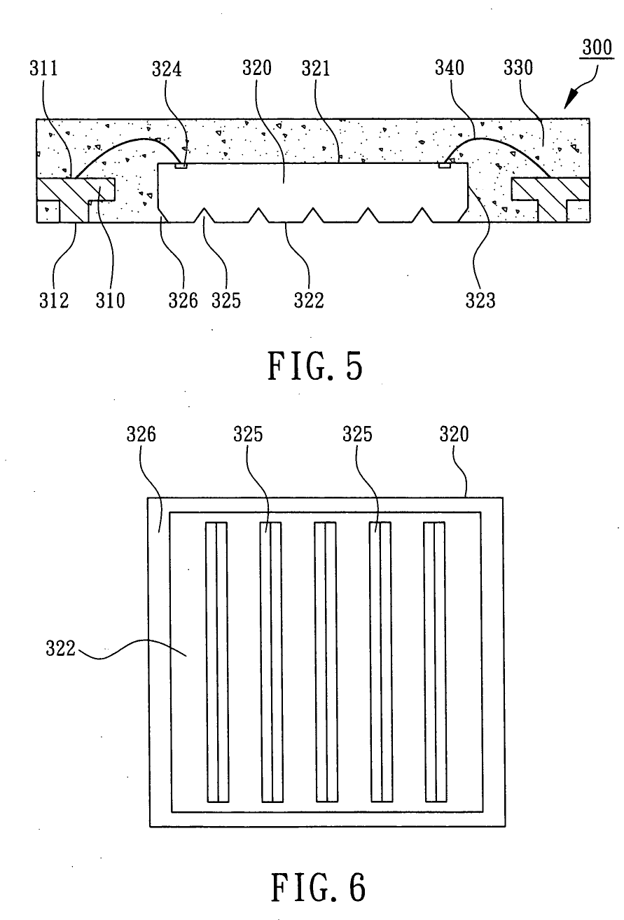

According to the third embodiment of the present invention, as shown in FIG. 5, a thin IC package 300 is a QFN (Quad Flat Leadless) package. The IC package 300 comprises a plurality of leads 310 of a lead frame as external terminals, a chip 320, and an encapsulant 330 where each lead 310 has an upper surface 311 and a bottom surface 312. The bottom surfaces 312 of the leads 310 are exposed from the encapsulant 330 for external connection. The chip 320 is surrounded by the leads 310 and located at a center of the encapsulant 330. The chip 320 has an active surface 321, a back surface 322, and a plurality of sidewalls 323 where a plurality of bonding pads 324 are formed on the active surface 321. The bonding pads 324 are electrically connected to the upper surface 311 of the leads 310 by a plurality of bonding wires 340. A plurality of slots 325 are formed on the back surface 322 of the chip 320. In this embodiment, the back surface 322 of the chip 320 is coplanar with the bottom surfaces of the encapsulant 330. As shown in FIG. 5, the slots 325 can be arranged in parallel and have a cross section of triangle. Preferably, a plurality of chamfered edges 326 are formed around the back surface 322 of the chip 320, as shown in FIG. 6. The encapsulant 330 encapsulates the upper surface 322 of the leads 310, the active surface 321 of the chip 320, the sidewalls 323, the chamfered edges 326 and the bonding wires 340 so that the chip 320 is embedded with only one surface 322 exposed. Since the back surface 322 of the chip 320 and the slots 325 are exposed from the encapsulant 330, therefore, the back surface 322 of the chip 320 has a larger heat dissipation area to enhance heat dissipation efficiency. Moreover, since the chamfered edges 326 are also encapsulated by the encapsulant 330, the adhesion between the chip 320 and the encapsulant 330 can be enhanced.

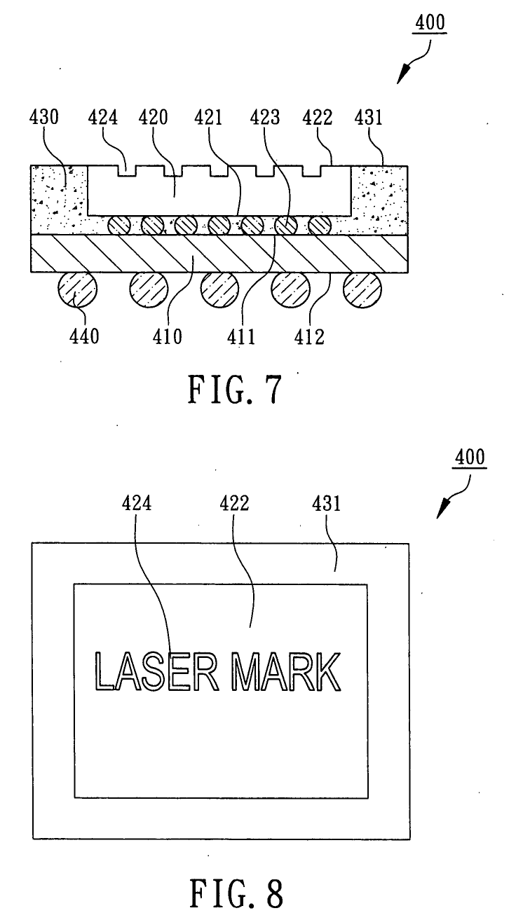

According to the fourth embodiment of the present invention, as shown in FIG. 7, a thin IC package to enhance heat dissipation from the back surface of a chip 400 is a BGA flip chip package. The thin package 400 comprises a substrate 410, a chip 420, and an encapsulant 430 where the substrate 410 has an upper surface 411 and a lower surface 412. The chip 420 has an active surface 421 and a back surface 422. In the present embodiment, the chip 420 is a bumped chip where a plurality of bumps 423 are formed on the active surface 421 of the chip 420 to electrically connect to the substrate 410 by flip-chip mounting. A plurality of slots 424 are formed on the back surface 422 of the chip 420. The encapsulant 430 are formed on the upper surface 411 of the substrate 410 by molding to encapsulate the active surface 421 of the chip 420 and the bumps 423. The back surface 422 of the chip 420 and the slots 424 are exposed from the encapsulant 430, for example, the slots 424 are exposed from the top surface 431 of the encapsulant 430 to increase the surface area of heat dissipation to further enhance heat dissipation efficiency. Furthermore, a plurality of external terminals 440 such as solder balls are placed on the lower surface 412 of the substrate 410. Referring to FIG. 8, preferably, the slots 424 can be formed as laser marks on the back surface 422 of the chip 420, such as trademark, specification, lot number, part number, which is exposed from the top surface 431 of the encapsulant 430 as an identification of the package 400.

The above description of embodiments of this invention is intended to be illustrative and not limiting. Other embodiments of this invention will be obvious to those skilled in the art in view of the above disclosure.

What is claimed is:

1. An IC package comprising:
an encapsulant;
a chip embedded in the encapsulant, the chip having an active surface, a back surface, and a plurality of sidewalls, wherein at least a slot is formed on the back surface; and a plurality of external terminals electrically connected to the chip and exposed from the encapsulant, wherein the active surface and the sidewalls of the chip are covered by the encapsulant with the back surface and the slot of the chip exposed from the encapsulant to enhance heat dissipation.

2. The IC package of claim 1, wherein the encapsulant has a bottom surface from where the external terminals, the back surface and the slot of the chip are exposed.

3. The IC package of claim 1, wherein the slot does not connect to the edges of the back surface of the chip.

4. The IC package of claim 1, wherein a plurality of the slots are formed as laser marks.

5. The IC package of claim 1, wherein the slot connects to the edges of the back surface of the chip.

6. The IC package of claim 1, wherein a plurality of the slots are arranged like a net.

7. The IC package of claim 1, wherein a plurality of the slots are parallel to each other.

8. The IC package of claim 1, wherein the cross section of the slot is triangular, rectangular, or semi-circular.

9. The IC package of claim 1, wherein the external terminals include the bottom surfaces of the leads of a lead frame or the extruded plated layers of a BCC (Bump Chip Carrier) package.

10. The IC package of claim 1, further comprising a heat spreader attached to the back surface of the chip.

11. The IC package of claim 1, further comprising a heat spreader in the encapsulant attached to the active surface of the chip.

12. The IC package of claim 1, wherein a plurality of chamfered edges are formed around the back surface of the chip to enhance adhesion between the chip and the encapsulant.

13. The IC package of claim 1, wherein a plurality of the slots on the back surface of the chip to form a plurality of integral thermal fins therefrom.

14. An IC package comprising:
a substrate having an upper surface, a lower surface, and an opening;
a chip disposed in the opening of the substrate, the chip having an active surface and a back surface, wherein at least a slot is formed on the back surface, a plurality of bonding pads formed on the active surface are electrically connected to the substrate; and
an encapsulant formed on the upper surface of the substrate and in the opening to embed the chip, wherein the back surface and the slot of the chip are exposed from the encapsulant to enhance heat dissipation.

15. The IC package of claim 14, wherein a plurality of external terminals are formed on the lower surface of the substrate, the back surface of the chip is coplanar with the lower surface.

16. The IC package of claim 14, further comprising a heat spreader attached to the back surface of the chip.

17. The IC package of claim 14, further comprising a heat spreader in the encapsulant attached to the active surface of the chip.

18. The IC package of claim 14, wherein a plurality of chamfered edges are formed around the back surface of the chip to enhance adhesion between the chip and the encapsulant.

19. The IC package of claim 14, wherein a plurality of the slots on the back surface of the chip to form a plurality of integral thermal fins therefrom.

20. An IC package comprising:
an encapsulant;
a chip embedded in the encapsulant except for only one surface exposed, wherein a plurality of slots are formed on the exposed surface; and
a plurality of external terminals electrically connected to the chip and extruding from the encapsulant.
